(19) United States
(12) Patent Application Publication
(10) Pub. No.: US 2017/0288114 A1
(43) Pub. Date: Oct. 5, 2017

(54) THERMOELECTRIC POLYMER COMPOSITES

(71) Applicant: THE JOHNS HOPKINS UNIVERSITY, Baltimore, MD (US)

(72) Inventors: Howard E. KATZ, Baltimore, MD (US); Robert M. IRELAND, Baltimore, MD (US)

(21) Appl. No.: 15/508,277

(22) PCT Filed: Sep. 4, 2015
(86) PCT No.: PCT/US2015/048665

§ 371 Date: Mar. 2, 2017

Related U.S. Application Data
(60) Provisional application No. 62/046,607, filed on Sep. 5, 2014.

(51) Int. Cl. H01L 35/24; C08L 65/00

(52) U.S. Cl. CPC H01L 35/24; C08L 65/00; C08L 2203/20; C08L 2205/025

(57) ABSTRACT

An embodiment of the present disclosure is directed to a thermoelectric polymer composite. The composite comprises: at least one polymer selected from semiconducting polymers and conducting polymers; and at least one particle inclusion having one or more dimensions of 1 millimeter or less and at least one dimension of 10 nanometer or more. A sufficient amount of the particle inclusion is distributed within the polymer so that the power factor of the composite is greater that the power factor of either the polymer or the particle inclusion separately.

### RELATED APPLICATIONS

This application claims priority from U.S. Provisional Patent Application Ser. No. 62/046,607, filed Sep. 5, 2014, which is hereby incorporated by reference in its entirety.

### FIELD OF THE DISCLOSURE

The present disclosure is directed to thermoelectric polymer composites, and in particular to thermoelectric polymer composites that include particle inclusions for increasing the composite power factor.

### BACKGROUND

There is growing interest in solution-deposited polymer-based composites for ambient temperature cooling and power generation on the microwatt-to-watt-scale where sufficient power is more critical than high efficiency. Such composites combine solution processing, mechanical flexibility, and potentially low thermal conductivity with sufficient power factor (PF), contributing to high values of the figure of merit, ZT=S²σT/κ, where S is Seebeck coefficient, σ is electronic conductivity, S²σ is PF, T is absolute temperature, and κ is thermal conductivity. Thermoelectric performance of hole-carrying (p-type) polymers has been enhanced so that ZT now exceeds 0.1. While ZT>1 is considered the threshold for general commercial viability, ZT of 0.1 is still an important milestone for any new class of thermoelectric material, or for applications where form and composition factors outweigh efficiency, such as medical or mobile applications.

Most prior work in polymer thermoelectrics has been done on hole-carrying (p-type) polymers, especially poly(ethylenedioxythiophene) (PEDOT), sometimes mixed with heavy element compound semiconductors, having PF values >100 μW/mK² that lead to ZT>0.1. PEDOT is currently the most studied TE polymer or host matrix for hybrid polymer-inorganic composites, with the highest ZT reported. It has been shown that PEDOT can exhibit ZT values as great as 0.4 through optimal doping.

There are far fewer reports of electron-carrying (n-type) thermoelectric polymers, which are needed for completing flexible thermoelectric modules. Of the currently available n-type materials, fullerenes and powder-processed organometallic poly(Ni 1,1,2,2-ethenetetrathiolate) derivatives have shown high thermoelectric performance. Zhu et al. achieved PFs from 6-60 μW/cmK² (S around −100 to −150 μV/K, and conductivities of 5-40 S/cm) from metal coordination n- and p-type structures, leading to ZT near 0.1 at ambient temperature and 0.2 at 130° C. Zhu et al., Organic thermoelectric materials and devices based on p- and n-type poly(metal thiolate)s, Advanced Materials, 2012. However, these materials are completely insoluble.

The few results obtained so far regarding solution-processable materials have been on imide-containing polymers, or imide-based small molecules, without inorganic additives. The first was an all solution-processable n-type polymer having a very simple chemical structure, for which S was around −40 μV/K. Schlitz et al. demonstrated solution doping of a high mobility n-type polymer, poly[N,N′-bis(2-octyl-dodecyl)-1,4,5,8-napthalenedicarboximide2,6-diyl]-alt-5,5′-(2,2′-bithiophene)] (P(NDIOD-T2), using dihydro-1H-benzoimidazol-2-yl (N-DBI) derivatives as potential dopants. Schiltz et al., Solubility-limited extrinsic n-type doping of a high electron mobility polymer for thermoelectric applications, Adv. Mater. 26, 2014, 2825-2830. Schiltz et al. achieved electrical conductivities of nearly 0.01 S/cm and PF of 0.6 W/mK². Segalman and coworkers showed record-high thermoelectric performance for solution-processed perylene diimide molecules, which could be designed with doping atoms separated by spacers, resulting in σ of 0.4 S/cm, S around −180 μV/K, and a PF of 1.4 μW/mK². R. A. Segalman, Power factor enhancement in solution-processed organic n-type thermoelectrics through molecular design, Advanced Materials 26, 2014.

Novel materials with enhanced theremoeletric performance and/or techniques for enhancing thermoelectric performance would be a welcome advancement in the art.

### SUMMARY

An embodiment of the present disclosure is directed to a thermoelectric polymer composite. The composite comprises: at least one polymer selected from semiconducting polymers and conducting polymers; and at least one particle inclusion having one or more dimensions of 1 millimeter or less and at least one dimension of 10 nanometer or more. A sufficient amount of the particle inclusion is distributed within the polymer so that the power factor of the composite is greater that the power factor of either the polymer or the particle inclusion separately.

Another embodiment of the present disclosure is directed to a thermoelectric device. The device comprises a first electrode and a second electrode. A thermoelectric composite is positioned between the first electrode and the second electrode so that when a temperature differential is applied across the thermoelectric composite, the thermoelectric composite is capable of generating a voltage between the first electrode and the second electrode. The thermoelectric composite comprises: at least one polymer selected from semiconducting polymers and conducting polymers; and at least one particle inclusion having one or more dimensions of 1 millimeter or less and at least one dimension of 10 nanometer or more. A sufficient amount of the particle inclusion is distributed within the polymer so that the power factor of the composite is greater that the power factor of either the polymer or the particle inclusion separately.

It is to be understood that both the foregoing general description and the following detailed description are exemplary and explanatory only and are not restrictive of the present teachings, as claimed.

### BRIEF DESCRIPTION OF THE DRAWINGS

The accompanying drawings, which are incorporated in and constitutes a part of this specification, illustrate an embodiment of the present teachings and together with the description, serve to explain the principles of the present teachings.

FIG. 1 illustrates chemical structures of poly(PyDI-ethynylene)-5FPE (P1), P(ND12OD-T2) (P2), PQT12 (P3), and PBTTT-C14 (P4), according to examples of the present disclosure.

FIG. 2 shows optical micrographs of SnCl₂ microstrostructure captured in a P1 polymer matrix by drop-casting from starting concentrations ranging 20-90 wt %, and of pure SnCl₂ drop-cast from solution on glass alone, according to examples of the present disclosure. Scale bars are all 100 μm.

FIGS. 3A and 3B show the Seebeck coefficient, electrical conductivity, and power factor are plotted versus concentration of initial tin(II) chloride precursor within a) P1 (FIG. 3A) and b) P2 (FIG. 3B) polymer matrices, according to examples of the present disclosure. Values are the average of at least 10 samples. Error bars are standard deviations.

FIG. 4 shows optical microscope images of P3 (PQT12) blended with 20, 40, and 60 wt % cobalt(III) acetylacetonate (from left to right, where top and bottom images show same concentrations at different magnification), according to examples of the present disclosure. Scale bars are all 100 μm.

FIG. 5 illustrates a side-view schematic illustration of a thermoelectric devise for taking S measurements, according to an example of the present disclosure.

FIG. 6 illustrates a thermoelectric device for harvesting energy, according to an example of the present disclosure.

FIG. 7 is an X-ray diffraction plot showing that pure SnCl₂ films are mostly amorphous, with very small peaks for metallic tin, and possibly tin(II) chloride or tin oxide, according to an example of the present disclosure.

FIG. 8 is an X-ray diffraction plot showing that composite films are mostly amorphous, with small peaks for metallic tin, tin(II) chloride, and tin oxide, according to an example of the present disclosure.

FIGS. 9A and 9B show linear Seebeck coefficient, log scale electrical conductivity, and log scale power factor are plotted versus concentration of starting zinc precursor for 9A) aqueous-based zinc solution in P1 and P2 and for 9B) anhydrous zinc oxide in P1, according to an example of the present disclosure. Values are the average of at least 5 samples.

FIG. 10 shows the linear Seebeck coefficient, log scale electrical conductivity, and log scale power factor are plotted versus concentration of starting Co((acac)3) in P3 obtained by drop-casting, according to an example of the present disclosure. Values are the average of at least 5 samples.

It should be noted that some details of the figure have been simplified and are drawn to facilitate understanding of the embodiments rather than to maintain strict structural accuracy, detail, and scale.

### DETAILED DESCRIPTION

Reference will now be made in detail to embodiments of the present teachings, examples of which are illustrated in the accompanying drawings. In the drawings, like reference numerals have been used throughout to designate identical elements. In the following description, reference is made to the accompanying drawing that forms a part thereof, and in which is shown by way of illustration a specific exemplary embodiment in which the present teachings may be practiced. The following description is, therefore, merely exemplary.

An embodiment of the present application is directed to a thermoelectric polymer composite. The polymer composite comprises at least one polymer and at least one particle inclusion. The polymer is selected from semiconducting polymers and conducting polymers. The at least one particle inclusion has one or more dimensions of 1 mm or less, such as 10 microns or less, or 1 micron or less. The particle is a domain of a solid phase material, rather than a single molecular unit. In an embodiment, the inclusions are not individual molecules, polymer chains (e.g., long chain of SiO or PN bonds or other polymers) or carbon nanotubes. In an embodiment, the particle inclusion has at least one dimension measurable along an arbitrary axis, x, of 10 nm or more and a second dimension that is measurable along an axis, y, that is perpendicular to the x axis, the second dimension being at least 3 nm or more. Individual molecules and polymer chains are generally excluded by these dimensions because most molecules have no dimension as large as 10 nm, and polymer chains generally do not have a “thickness” or diameter of as much as 3 nm. A third dimension measurable along an axis z that is perpendicular to the x axis and y axis can be arbitrarily thin to allow for very thin flakes or platelets, for example. A sufficient amount of the particle inclusion is distributed within the polymer so that the power factor of the composite is greater that the power factor of either the polymer or the particle inclusion separately.

The polymers employed in the thermoelectric polymer composite can be any suitable semiconducting or conducting organic polymers, including either n-type or p-type polymers. Examples of suitable semiconducting and conducting polymers are well known in the art. As used herein, the term “semiconducting polymer” is defined to mean organic polymers having a conductivity in their pure form ranging from about 10⁻⁶ S/cm to about 1000 S/cm. The term “conducting polymer” is defined to mean any organic polymer having a conductivity at the higher range of conductivities for a semiconducting polymer, e.g. >0.01 S/cm. The term encompasses polymers which may attain this higher range of conductivity as the result of the incorporation of additives, often termed “dopants”.

### N-Type Polymers

In one embodiment, the polymer is an n-type polymer, meaning a semiconducting or conducting polymer where the majority charge carriers are electrons. Examples of suitable n-type polymers include polymers comprising at least one polymer unit chosen from pyromellitic diimide units, napthalenetetracarboxylic diimide units, perylenetetracarboxylic diimide units, heterocyclic tetracarboxylic diimide units, cyano-substituted vinyl groups, cyanomethylidene-substituted unsaturated rings, fullerene units, pyrazinophthalimide units, and triazoledipyridyl units. Any one, two, three, four or more of the n-type polymer units can be employed in the polymer. Enhancement of the n-type activity can occur when cationic species including protons or metal ions coordinate to sites on the polymers. Side chains can be appended to the various subunits to promote solubility, compatibilization with additives, processability, chemical stability, and the like.

The n-type polymers preferably comprise aromatic or heteroaromatic tetracarboxylic diimide subunits, such as pyromellitic Dilmide (PyDi) units. Optional unsaturated carbon groups, including alkyne linkages such as ethynylene, can be attached to a ring carbon of the pyromellitic Dilmide group. The imide nitrogens on these subunits are preferred sites for side chain attachment. Such side chains can include linear alkyl chains preferably 4-12 carbons long, branched alkyl chains 6-22 carbons long, and semifluorinated alkyl chains comprising 1-6 CH₂ or CH₃ groups and 1-10 CF₂ or CF₃ groups. Phenylene and oxy groups can be interposed among the carbons of these side chains.

One or more additional conjugating subunits, such as 1,4-phenylenediyl, 1,2-ethylidene, 1,2-ethynylidene, and diketopyrrolopyrrole, may be present in the n-type semiconducting polymers. Still other conjugating subunits can include, for example, 2,6-naphthalenediyl, 2,5-thiophenediyl, 5,5′-(2,2′-bithiophenediyl), and similar subunits with the possibility that heteroatoms, such as N or O, of the above listed conjugating subunits could be substituted for some of the ring carbons and/or that side chain substituents could be substituted for some of the hydrogen on the ring, if stability and conjugation are maintained.

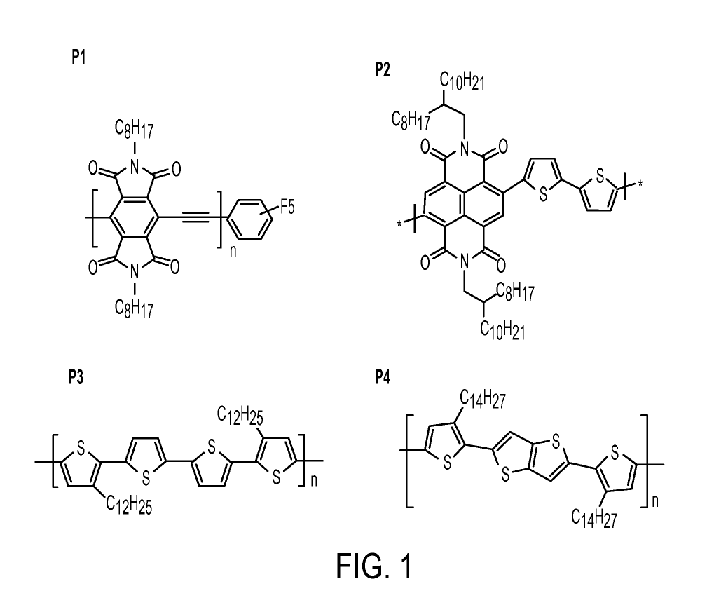

Examples of suitable n-type polymers include PyDi-ethynylene polymers, such as poly(PyDi-ethynylene) and poly(PyDi-ethynylene)-5FPE (also known as “5FPE-PyDI”, and sometimes referred to herein as P1); and poly{[N,N′-bis(2-octyldodecyl)-naphthalene-1,4,5,8-bis(dicarboximide)-2,6-diyl]-alt-5,5′-(2,2′-bithiophene)}, also known as P(NDI20D-T2) (commercially available as Polyera Activink™ N2200 from Polyera Corporation of Skokie, Ill.) and referred to herein as P2). Chemical structures for P1 and P2 are shown in FIG. 1, where “n” refers to the number of repeating units. The ‘n’ in the formulae of FIG. 1 represents the number of repeating units of the polymer. The structure of P1 includes a pentafluorophenyl end cap. In an embodiment, an n-type polymer the same as P1 but without the end caps could also be used.

The weight average molecular weight of the n-type polymers can range, for example from 1000 daltons or more, such as 2000 daltons to about 200,000 daltons, or about 10,000 daltons to about 150,000 daltons or about 20,000 daltons to about 150,000 daltons. Polydispersity for the polymers can be 1 or greater, such as from about 1.5 to about 10, or about 1.6 to about 8.

### P-Type Polymers

In another embodiment, the polymer is a p-type polymer, meaning a semiconducting or conducting polymer where the majority charge carriers are holes. Examples of suitable p-type polymers include polymers comprising at least one polymer unit chosen from thiophene units, 3-alkylthiophene units, thienothiophene units, pyrrole units, furan units, carbazole units, aniline units, ethylenedioxythiophene units, ethylenedithiolate units, methoxyphenylenvinylene units, or dialkoxyphenylenevinylene units. Any one, two, three, four or more of the p-type polymer units can be employed in the polymer.

As mentioned above, additional conjugating subunits, such as 1,4-phenylenediyl, 1,2-ethylidene, 1,2-ethynylidene, and diketopyrrolopyrrole, may be present in either p-type or n-type semiconducting polymers. Still other conjugating subunits can include, for example, 2,6-naphthalenediyl, 2,5-thiophenediyl, 5,5′-(2,2′-bithiophenediyl), and similar subunits with the possibility that heteroatoms, such as N or O, of the above listed conjugating subunits could be substituted for some of the ring carbons and/or that side chain substituents could be substituted for some of the hydrogen on the ring, if stability and conjugation are maintained.

Other examples and designations of p-type polymers include polythiophene (PT), polyalkylthiophene, polyaniline, polyanaline, polyacetylene, polypyrrole, poly(p-phenylene sulfide), poly(p-phenylene vinylene) (PPV), polyindole, polypyrene, polycarbazole, polyazulene, polyazepine, polyfluorene, and polynaphthalene. As was described for n-type polymers, side chains may be appended to enhance various physical and chemical attributes. Alkyl chains of about 4 to about 12 carbons in length are preferred substituents for thiophene rings and other subunits of p-type polymers.

In an embodiment, suitable p-type polymers include PQT12, referred to herein as P3 and PBTTT-C14, referred to herein as P4. Chemical structures for P3 and P4 are shown in FIG. 1.

The ‘n’ in the formulae of FIG. 1 represents the number of repeating units of the polymer. Example values for n can range from about 5 to about 1000, such as about 20 to about 1000 or about 50 to about 500 or about 50 to about 250. Values for n can be chosen to achieve the desired solid film organization and a usable solubility. The desired values for n may depend on the particular repeat units employed, with polymers having larger repeat units or greater numbers of ring structures potentially employing lower values for n. Similar numbers of repeat units can be employed for P2 polymers.

Polymer blends can be employed in the composites of the present disclosure, including blends of any of the above n-type polymers to form an n-type composite or any of the above p-type polymers to form a p-type composite. In an embodiment, the blend can comprise at least two polymers of differing carrier energy levels. An example of a p-type polymer blend comprises both PQT12 and PQT12S (same as PQT12 except for sulfur atoms are inserted between the thiophene rings and the dodecyl side chains, making them dodecylthio groups, which results in lower carrier energy level and easier hole-doping when compared to PQT12). The same principle can be applied to n-doped polymers. For example, any of the above n-type polymers can be employed as a first polymer, which is blended with a second polymer that is the same as the first polymer except that it is synthesized with additional halo or cyano substituents to lower its carrier (electron) energy level. Thus, the blend includes a first polymer with a relatively high carrier energy level and a second polymer with a lower carrier energy level compared with the first polymer.

### Particle Inclusions

The particle inclusions employed in the thermoelectric polymer composite can be any suitable inclusion that increases the power factor of the composite to be greater than the power factor of either the polymer or the particle inclusion separately. The particle inclusions can be metal-element-atom inorganic compounds or metal-element-atom organic compounds.

In an embodiment, the particle inclusion is capable of donating an equilibrium concentration of charge carriers to the polymer. The mechanism by which this occurs in the present invention is different from traditional chemical doping of semiconducting polymers. In traditional chemical doping, an additive is provided where electron donation from the molecules of the additive to an n-type polymer, or acquisition by the molecules of the additive from a p-type polymer, is favored to be more than 50% complete, as judged by the proportions of additive molecules ionized or not ionized by this process of electron donation or acquisition, at room temperature. In contrast, in the present embodiment of the invention, the particle inclusion electron donation to an n-type polymer, or acquisition of electrons from a p-type polymer, is less than 50% complete, such as less than 40%, 30%, 20%, 10% or 1% complete, as judged by the proportion of formula units in the particle inclusion material being ionized or not ionized (or in other words, the fraction of molecular formula units in the inclusions that are oxidized or reduced) at room temperature. One method for measuring the fraction of molecular formula units in the inclusions that are oxidized or reduced is by spectroscopy. It may be possible to evaluate spectroscopic contributions of oxidized and reduced species in the polymer and/or the particle inclusion (the polymer spectra giving an indication of particle inclusion activity) by spectroscopic peaks, as determined, for example, by visible, near infrared, UV or ordinary infrared spectroscopy, including the Raman implementation of infrared. These peaks can be calibrated in separate spectroelectrochemical experiments.

The lower magnitude of particle inclusion electron donation to an n-type polymer, or acquisition of electrons from a p-type polymer, effectively results in lower doping levels of the polymer by the particle inclusion than would occur with particle inclusions having a higher magnitude of electron donation or acquisition. It is believed that such weakly-doping microstructured inclusions can act synergistically with both n- or p-type polymers to give enhanced thermoelectric performance. The lower doping level, on a molecular formula basis, can arise from more than one mechanism. While not being limited to these specific descriptions, one such mechanism is to have a particle inclusion material where the formula unit oxidation or reduction potential is more negative or positive, respectively, than the reduction or oxidation potential, respectively, of the p or n-type polymer, respectively, but where there is still an entropy-driven electron transfer. The proportion of particle inclusion formula units being oxidized or reduced, in the case where all of them are accessible to the polymer and distributed throughout the polymer sample, can be governed by a form of the Nernst equation, well known in the art of electrochemistry. The Nernst equation expresses this proportion as a function of the number densities of oxidizable/reducible polymer subunits and particle inclusion formula units, and the voltages at which each can be oxidized and reduced relative to a standard electrical potential.

Another such mechanism is to have a nanoparticle inclusion where the formula unit oxidation or reduction potential is more positive or negative, respectively, than the reduction or oxidation potential, respectively, of the p- or n-type polymer, respectively, but where the work of extracting charges from the interior of the particle inclusion inhibits >50% electron transfer. In other words, the driving force for electron transfer would be governed not only by the voltages for oxidation and reduction of the polymer and the particle inclusion formula units, but also by overcoming the force of attraction between holes and electrons within the particle inclusion to move a hole or electron out of the inclusion and into the polymer and/or out of the polymer and into the inclusion, a process called charge separation. These attractive forces are governed by the dielectric constants of the media in which the charges may be moved, with lower dielectric constants increasing the attractive force and decreasing the driving force for charge separation, as expressed, for example, by forms of the well-known Coulomb's Law.

In a third mechanism, an interfacial dipole moment at the boundary between the particle inclusion and the polymer creates an offset of band or orbital energies in the polymer near the boundary relative to the energies in the bulk of the polymer, so that electron transfer occurs between the particle inclusion and the polymer near the boundary, but not the polymer away from the boundary. Other mechanisms for increasing charge density may pertain as well.

It is possible for the particle inclusions to increase conductivity by increasing the charge carrier mobility of the semiconducting polymer. For example, the surface of the particle inclusion can induce a more favorable morphology for charge hopping among subunits of the polymer. Alternatively, an intermixing of components of the polymer and the particle inclusion, near the polymer inclusion interface, can create a region of higher charge carrier mobility. Other mechanisms for increasing mobility may pertain as well.

The particle inclusions preferably increase Seebeck coefficient in addition to increasing conductivity. In some embodiments, the particle inclusions change the density of state profiles and/or the distribution of charge carriers among energy levels in ways that are favorable for higher Seebeck coefficient. For example, the particle inclusion can result in the introduction of states that are lower in energy than the states in which charge would have otherwise been transported in the polymer, and/or the adjustment of the Fermi level to near the energy of the new states. These changes are expected to increase the Seebeck coefficient, as has been previously described. See Poehler, T. O. and Katz, H. E., “Prospects for Polymer-based Thermoelectrics: State of the Art and Theoretical Analysis,” Energy and Environmental Science, 5, 2110-2115 (2012); and Sun, J., Yeh, M., Jun. B. J., Zhang, B., Feser, J., Majumdar, A. and Katz, H. E., “Simultaneous Increase in Seebeck Coefficient and Conductivity in a Doped Poly (alkylthiophene) Blend with Defined Density of States” Macromolecules, 43, 2897-2903 (2010), the disclosures of both of which articles are incorporated herein by reference in their entirety.

The inclusions can be millimeter sized particles or smaller, meaning that the inclusions have a least one dimension that is 1 mm or less, preferably 10 microns or less, and even more preferably 1 micron or less. However, the particle inclusion also has at least one dimension of 10 nm or more, and a second dimension of 3 nm or more, e.g., the particle is a domain of a solid phase material, rather than a molecular unit.

For example, particle inclusions can be micro or nanosized. There are also several competing arguments for either macrocrystals or nano-sized inclusions being more desirable. For one, smaller dopants have high tendency to diffuse in organic systems, leading to detrimental instability. M. L. Tietze, et al., Self-passivation of molecular n-type doping during air exposure using a highly efficient air-instable dopant, PSS, 2013, the disclosure of which is hereby incorporated by reference in its entirety. Nanostructuring increases surface area to volume ratio greatly at cost of greater series contact resistances. However, phononic thermal conductivity is greatly reduced due to the abundance of interface with nanostructuring. The control of particle growth rates leading to optimized power factors and reduced phononic thermal conductivity would be ideal for further increases in composite ZT.

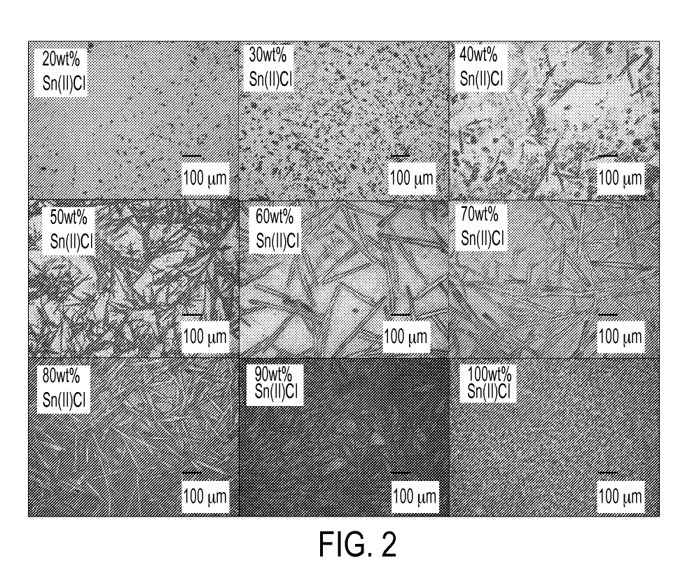

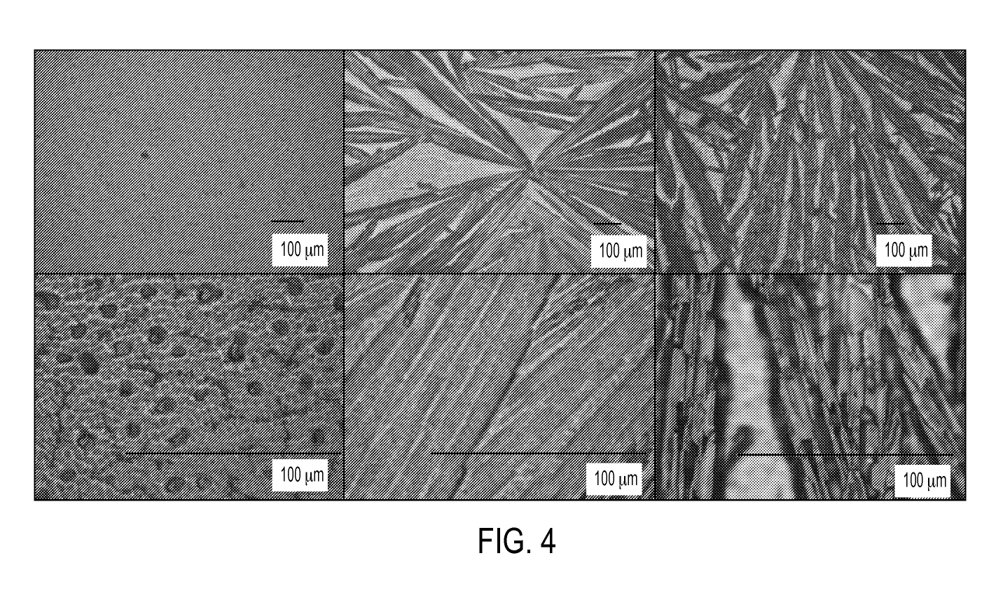

The inclusions can be crystalline or amorphous in structure and have any suitable structure or shape, including rods, prisms, flakes, platelets, spherical or rounded particles, microcrystals, nanocrystals and nanowires among others. Examples of microstructured inclusions are shown in FIGS. 2 and 4. In an embodiment, the particles can have a high aspect ratio of greater than 3:1, such as 5:1 to 50:1, or 7:1 to 25:1.

Any suitable concentration of inclusions can be employed in the composites so as to provide the desired composite properties. Concentrations of inclusions in the composites can range, for example, from about 10 wt % to about 80 wt %, such as about 40 wt % to about 70 wt %, based on the total weight of the dry composite.

### Particle Inclusions for n-Type Polymers

The particular inclusions employed can depend on the type of polymer. For instance, for n-type polymers, the particle inclusions can be, for example, inorganic metal-atom compounds displaying any one or more of the useful phenomena discussed herein along with the selected n-type polymer, such as donating an equilibrium concentration of charge carriers to the polymer, increasing conductivity by increasing the charge carrier mobility of the semiconducting polymer, or increasing the Seebeck coefficient. It is preferable that these compounds comprise metal elements that are naturally abundant and/or have relatively low toxicity. Accordingly, in some embodiments, the particle inclusions comprise two or more elements selected from Sn, Zn, Al, CI, O and S, wherein the compound includes at least one of Sn, Zn and Al and one of Cl, I, and S. Examples of such compounds include tin chlorides, zinc oxides, zinc sulfides and tin sulfides. Such compounds can be modified with uncompensated easily oxidized atoms such as Mg, Li, and the like to increase doping capability.

### Particle Inclusions for p-type polymers

For p-type polymers, the particle inclusions can comprise oxidizing metal ions such as vanadium (IV), chromium (III), manganese (III, manganese IV, iron(III), cobalt(III), nickel(II), and molybdenum (VI). Examples of particle inclusions based on such ions are molybdenum trioxide, Cobalt (III) acetylacetonate, Cobalt(III) trifluoroacetylacetonate, Iron (III) trifluoroacetylacetonate, Iron (III) hexafluoroacetylacetonate, manganese (III) acetylacetonate, manganese (III) trifluoroacetylacetonate and manganese dioxide. Other numbers of fluoride or other halide groups can be placed on the acetylacetonate ligands. Other ligands, such as pyridyl, carbonate, phosphate, sulfate, fluoride, chloride, or cyano ligands, may be used as well, provided they remain linked to the particle inclusion subunits under operating conditions.

The particle inclusions can be mixed into the polymer or grown within the polymer from a precursor solution (“In situ fabrication”). Techniques for mixing or forming the inclusions in situ are well known in the art. For instance, in situ methods can include mixing the inclusion compounds dissolved in solution into the polymer material, followed by removal of the solvent and precipitation of the particle inclusions in the polymer using any suitable evaporation and/or heating techniques. The composites are generally formulated as a liquid, which can be deposited on a suitable substrate using any suitable liquid deposition techniques, such as drop-casting, dip-casting or spin-casting. In in situ techniques, the inclusions may form after deposition of the composite on the substrate, such as during drying of the deposited film.

In situ fabrication of inorganic particles within the polymer matrix may contribute several advantages besides allowing facile “one-pot” preparation. Polymer-assisted growth has been shown to improve interfacial interactions, including electronically driven interactions between polymer and as-grown particles, such as those described above. For example, cadmium telluride nanocrystals were synthesized in poly(3-hexylthiophene) without use of surfactants. Chand et al., In-situ growth of cadmium telluride nanocrystals in oly(3-hexylthiophene) matrix for photovoltaic application. J. Appl. Phys. 2011, 110, 044509. These studies reveal that the nanocrystals work as transport media, which are bound to polymer via dipole-dipole interactions and form a charge transfer complex, facilitating percolation pathways for charge transport.

In addition to the weakly doping inclusions discussed above, the composites of the present disclosure can also include one or more strongly doping inclusions. An example of a strongly p-doping inclusion for a p-type polymer is F4TCNQ, which is 2,3,5,6-tetrafluoro-7,7,8,8-tetracyanoquinodimethane, a well known compound in the art. An example of a strongly n-doping inclusion for an n-type polymer is sodium naphthalide. For purposes of the present disclosure, a strongly doping inclusion is defined to be an additive where electron donation from the molecules of the additive to an n-type polymer, or acquisition by the molecules of the additive from a p-type polymer, is favored to be more than 50% complete, as judged by the proportions of additive molecules ionized or not ionized by this process of electron donation or acquisition, at room temperature.

The power factor realized by the thermoelectric composite will vary widely depending on the materials employed. In an embodiment, the power factor can be 1 μW/mK² or more, such as greater than 50 μW/mK² or greater than 100 μW/mK². The Seebeck coefficient can be greater than 50 microvolts/degree K, such as greater than 100 microvolts/degree K, greater than 500 microvolts/degree K or greater than 1000 microvolts/degree K.

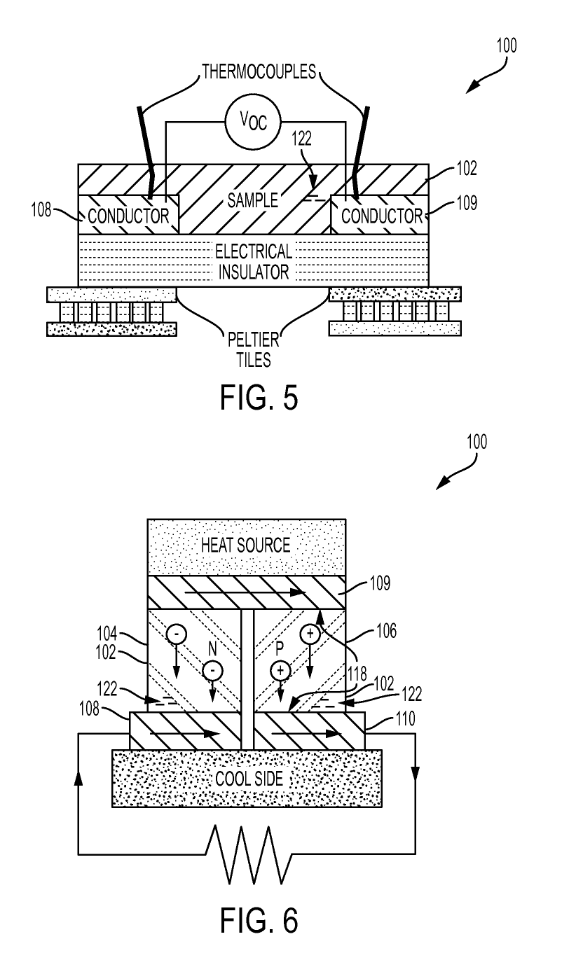

A variety of thermoelectric devices are well known in the art for a variety of applications, including harvesting energy (e.g., batteries, thermoelectric generators), directing heat (e.g., a thermoelectric cooler), as thermocouples for measuring temperature differences and so forth. FIGS. 5 and 6 illustrate exemplary thermoelectric devices 100 employing the composites of the present disclosure. One of ordinary skill in the art would readily understand how to employ the composites of the present disclosure in such devices. Such devices generally employ one or more composite materials 102, which in the present application includes at least one of the thermoelectric composites of the present disclosure. For example, such thermoelectric composites 102 can include an n-type composite 104, a p-type composite 106 or both an n-type and a p-type composite. An example of such a device that employs both n-type and p-type composites is shown in FIG. 6. As is readily understood by those skilled in the art, the thermoelectric composite or composites 102 are positioned between two or more conductors (also known as electrodes) 108, 109, 110 in the device so that when a temperature differential is applied across the thermoelectric composite so that the temperature is different in the two regions of the composite contacted by the electrodes, a voltage is generated between the electrodes.

In embodiments where the inclusions have high aspect ratios, differences in the power factor can be achieved depending on whether the inclusions are aligned in a particular direction with respect to the electrodes (or electric fields). Referring to FIGS. 5 and 6, for a given composite material, increased power factors can be achieved when the majority of inclusions 122 are oriented so that the length dimension is perpendicular to the electrodes 108,109,110 (parallel to the electric fields), while relatively smaller power factors are achieved when the majority of inclusions are oriented so that the length dimension is parallel to the electrodes 108,109,110 (perpendicular to the electric fields). The phrase “majority of inclusions” is defined herein to mean more than 50% of the inclusions. In other examples, 80% or more of the inclusions, such as 90-100% of the inclusions are aligned as described above. It should be assumed that the long axes of inclusions 122 are all substantially parallel to the major plane of the substrate and thermoelectric polymer composite film. Orientations are in the two dimensions parallel to those planes. Techniques for aligning particles are known in the art, such as flow aligning during formation of a solid material from a mobile phase, growth of particles influenced by patterned interfaces or patterned features in the substrate on which a material is grown, alignment under the influence of electrical or magnetic fields, or the like.

### EXAMPLES

A pyromellitic diimide (PyDI) polymer with pentafluorophenyl end caps (shown in FIG. 1 as P1), mixed with in situ-crystallized SnCl₂ to form a polymeric thermoelectric material. The poly(PyDI-ethynylene) polymer with pentafluorophenyl end caps is abbreviated PyDI-5FPE. Other composites were made with a commercially available n-type polymer (Polyera N2200), an alternative additive (ZnO), and analogous p-type polymers (PQT12 and PBTTT with cobalt(III) acetylacetonate (Co(acac)₃)), as described below, to show more broadly that weakly-doping microstructured inclusions can act synergistically with both n- or p-type polymers to give enhanced thermoelectric performance. FIG. 1 shows the chemical structure for the polymers used in the Examples below.

### Example 1: SnCl₂ in P1 and P2

SnCl₂ from 0 to 90 wt % was separately added to polymers P1 and P2 using the same procedure for each polymer, as follows. Each polymer was first weighed in a glass vial and mixed at 10 mg/ml in an organic solvent, such as toluene. Inorganic powder (SnCl₂) was measured in a separate vial and mixed at 10 mg/ml with the same solvent. The polymer was placed on a hot plate and held at 80° C. while solutions of the inorganic powder were sonicated for at least 30 minutes, becoming cloudy white. The polymer was blended in the desired concentration with the solution of inorganic powder using a pipette, and vigorously stirred for 10 minutes before drop-casting. The final blend was dropped by pipette into 2D wells (fabricated by laying a pattern of Novec fluorinated polymer) on glass substrates having pre-deposited gold electrodes. The result was a square cm film with 1-2 micrometer thickness, lying between two gold electrodes having a 0.2 cm gap and 0.5 cm width. The solvent was allowed to evaporate overnight (samples kept in petri dish), and elongated crystals were observed the next day. Next, the samples were placed in vacuum overnight at 100° C. to remove residual solvent and water. Just before taking electrical measurements, the films were held at 150° C. for 10-30 minutes and left to cool down.

The incorporation of SnCl₂ and subsequent drop-casting or spin-casting on glass substrates resulted in spontaneous formation of tin-based microcrystals within the polymer matrix during solvent evaporation. FIG. 2 shows laser optical micrographs of SnCl₂ in PyDI-5FPE for concentrations 20-90 wt %, and for pure SnCl₂ films. The pure SnCl₂films were processed exactly the same way as composites, meaning that the powder was dispersed in organic solvent but not mixed with polymer, just drop-cast or spincoated onto the substrate utilizing the same conditions.

P1 was particularly effective at promoting, or allowing, SnCl₂ micro/nano-structure growth. Elongated microcrystals were observed for starting SnCl₂ concentrations above 30 wt %, having aspect ratios >10. Crystals obtained from initial concentrations of 60-80 wt % SnCl₂ resulted in the most prominent shapes (sharper interfaces) and greater monodispersity, reaching widths of 10-40 μm and lengths of 100-400 μm. Spin-casting resulted in very well dispersed particulates, having significantly reduced dimensions, but increased homogeneity and still showing rod- and bar-like structures. Samples with 40, 60, and 80 wt % SnCl₂ were made by spin-casting.

Clusters and elongated crystals grown in the polymer matrix both appear to be mostly SnCl₂, possibly with some metallic tin and tin oxide, according to energy dispersive spectroscopy (EDS) utilizing a scanning electron microscope (SEM), X-ray photoelectron spectroscopy (XPS), and X-ray diffraction (XRD). EDS showed that crystals have high SnCl₂ content but also have some oxide presence, and that there is essentially no difference in the composition of different structures/shapes (clusters vs. crystals vs. pure film).

It was observed that the SnCl₂ additive was dispersed homogeneously within the polymer at a molecular level in addition to the secondary phase particulates at micrometer scale that are more easily observed. XPS of hybrid samples and pure SnCl₂ films confirmed the presence of the elements tin and chlorine. Small shift of composite XPS spectra to lower binding energies than pure tin chloride films may suggest that polymer-grown crystals have lower work function (like Sn₂O₃ or Sn₃O₄, which are more stable). Lower work function was found to be consistent with preliminary scanning Kelvin probe microscopy (KPM) results. KPM shows that the polymer chemical potential is pulled towards vacuum and SnCl₂ is pushed away from vacuum at the interface, which suggests that electrons accumulate in the polymer at their interface, with negative end of the interfacial dipole within the polymer. If pure and polymer-grown tin phase samples have the same electronic behavior then band-bending at the interface is highly likely. This band-bending will create occupied states at energies offset from the lowest unoccupied orbitals of the pure components, playing a vital role in enhancing the magnitude of S.

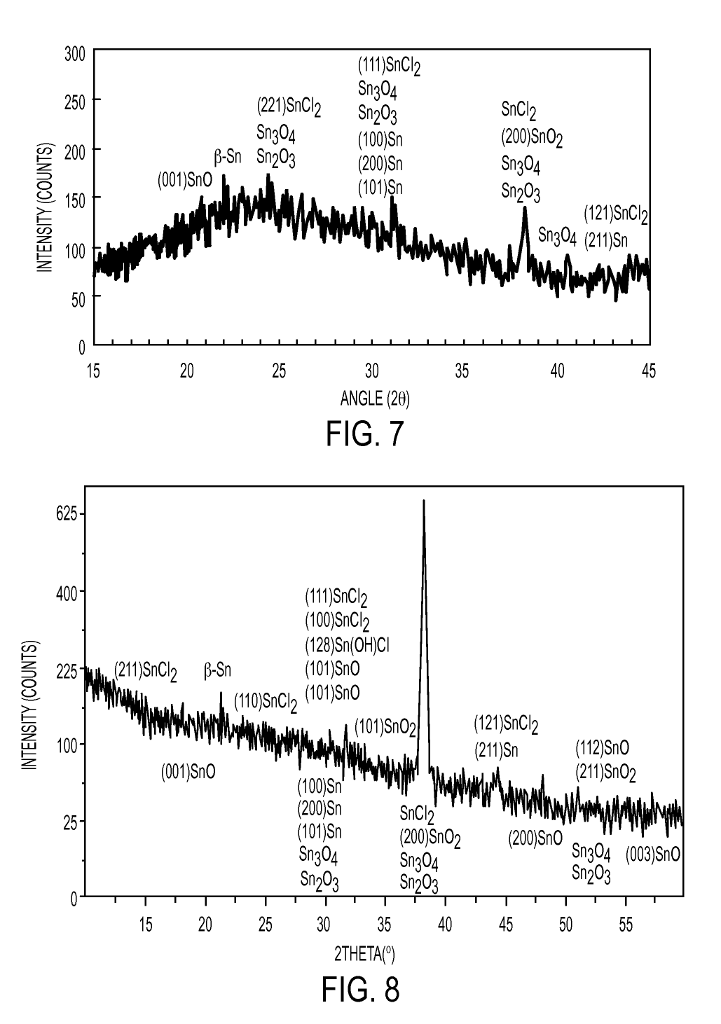

XRD suggests multiple phases, with similarities between different macroscopic shapes. Additional relatively small peaks can be indexed to tin metal, indicating that substantial volumes of tin particles are produced, either within or on the surface of SnCl₂ particles or the polymer. Characteristic peaks belonging to other phases such as tin oxide are also detected, demonstrating that the obtained product is composed of multiple hybrid structures and interfaces. X-ray diffraction shows that pure SnCl₂ films are mostly amorphous, with very small peaks for metallic tin, and possibly crystalline tin(II) chloride or tin oxide, as shown in FIG. 7. The polymer-grown tin structures formed in P1 also exhibit very similar phases (still having relatively low, broad peaks, as shown in FIG. 8.

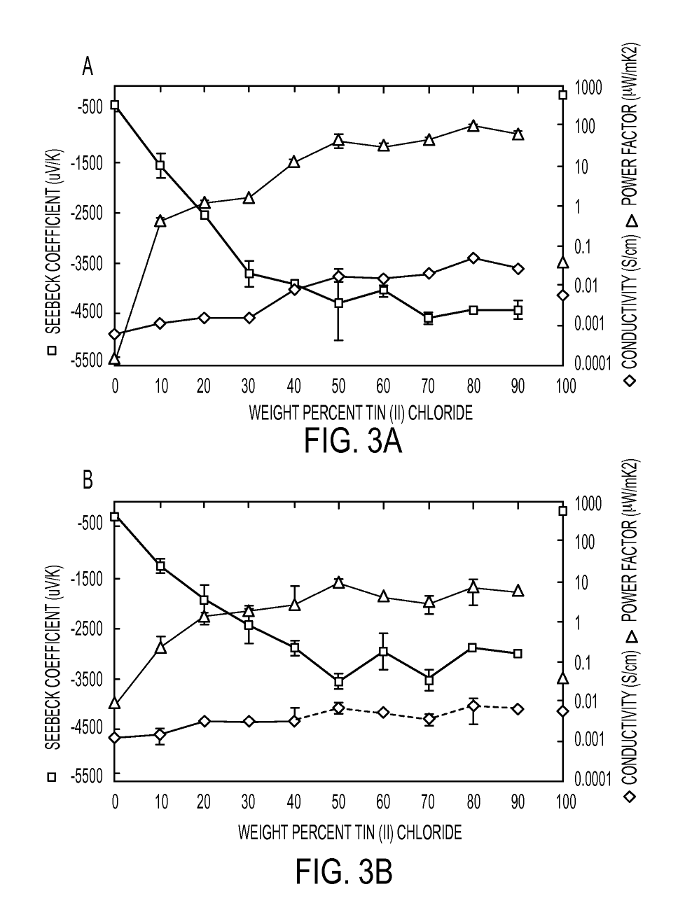

FIG. 3 shows the S, σ, and PF as function of SnCl₂ concentration in polymer matrices P1 and P2, respectively prepared by drop-casting. Standard thin-film thermoelectric measurement techniques were used, taken on a setup shown in FIG. 5, utilizing preferred electrode geometry that reduces measurement error, as reported in a paper by S. van Reenen et al., Correcting for contact geometry in Seebeck coeeficient measurements of thin film devices, Organic Electronics 15, 2014, 2250-2255, the disclosure of which is hereby incorporated by reference in its entirety. In particular, referring to FIG. 5, the length of electrodes was 10 mm (into the page) and width between electrodes was 2 mm. The S was measured with the sample mounted between a pair of Peltier heater-cooler tiles, with one electrode of the sample over each tile. Thermal EMF (ΔV) and temperature difference (ΔT) were measured simultaneously by probing the pair of electrodes with a source meter and thermocouples. Resistance was measured by 4-probe technique to minimize contact resistance, and conductivity was calculated using the physical dimensions of each device. All devices were tested under ambient conditions in air, but protected from light and convection. The measurements of S, σ, and PF were reported in a paper by Robert M. Ireland, et al., entitled, “ZT>0.1 Electron-Carrying Polymer Thermoelectric Composites with in-situ SnCl₂ Microstructure Growth”, Adv. Sci. 2015, 2, 1500015, the disclosure of which paper is hereby incorporated by reference in its entirety. The values in FIG. 3 are averages over at least 10 samples, taken from 3-5 repeated experiments, balancing statistical significance with the consideration that it takes about 1 hour for each run. As shown in FIG. 3A, P1 showed modest a in its undoped form (0.00057 S/cm), and a significant S (−380 μV/K). As shown in FIG. 3B, P2 showed greater σ (0.00124 S/cm), as expected due to higher intermolecular overlaps of diimide cores, resulting in much greater PF despite its lower intrinsic S (−280 μV/K). PFs were 0.00014 and 0.0095 μW/mK² for P1 and P2, respectively. The PF value for the pristine P2 was almost one tenth the value recently reported for a doped P2 system by R. A. Schiltz et al., in a paper entitled, “Solubility-limited extrinsic n-type doping of a high electron mobility polymer for thermoelectric applications,” Adv. Mater. 26, 2014, 2825-2830, the disclosure of which is incorporated herein by reference in its entirety.

SnCl₂ evaporated onto glass, nominally 50 nm thick, showed PF an order magnitude greater than does drop-cast SnCl₂, about 0.16 and 0.038 μW/mK², respectively. Evaporated and drop-cast pure SnCl₂ both show a around 4-5×10⁻³ S/cm, but the S was apparently increased by a factor of five when sublimed (which presumably forms more pure and crystalline solids), reaching about −530 μV/K. The sublimed material formed a film comprising multiple natural structures including elongated crystals, planar hexagonal crystals, and ribbons/sheets, resulting in a relatively rough and non-continuous film.

Power factors (PFs) of the hybrid composites were greater than those of any of the individual components, reaching 50 to 100 μW/mK² for SnCl₂ precursor concentrations above 50 wt % blended with P1. It appears that in situ microwire/nanostructure growth of SnCl₂ enormously increases S, and possibly σ of the polymer. By contrast, well-dispersed spherical clusters are obtained in P2. S increases significantly for P1 with increasing concentration of SnCl₂, saturating around −4500 μV/K above 50 wt % SnCl₂. σ increases only slightly for P1 hybrids with low concentrations of SnCl₂, consistent with the weak doping hypothesis and also with interfacial polarity measured by scanning KPM. σ increases sharply between 30 and 50 wt % and remains constant up to 90 wt % SnCl₂, leveling at about 0.05 S/cm. A strong increase in conductivity appears to be correlated with overlapping of the elongated Sn-containing crystals, as they reach sufficient size to create a percolated network above 40 wt % SnCl₂. Utilizing P2 as the polymer host matrix showed a similar trend as P1 blended with SnCl₂, but lower PFs closer to 10 μW/mK² were obtained. Though with a much lower σ, the PFs are on par with high performance p-type hybrid composites.

Values of κ of polymers and composites were measured using the femtosecond laser-based transient thermoreflectance method. The κ value measured was 0.14 W m⁻¹ K⁻¹ for both P1 and P2 with an uncertainty of 0.02 W m⁻¹ K⁻¹ while the heat capacity was 1.4 J cm⁻³ K⁻¹ with an uncertainty of 0.2 J cm⁻³ K⁻¹. The measurements on the drop-cast composites indicate that values of κ are only slightly increased relative to pristine polymers. The κ value was 0.18 W m⁻¹ K⁻¹ for 80 wt % SnCl₂/PyDI and 0.21 W m⁻¹ K⁻¹ for 20 wt % SnCl₂/PyDI using a multiple location and multiple spot-size sampling technique. The thermal conductivity of composites depends on the volume fraction, morphology, the thermal conductivity of the polymer and the inorganic crystals, and the thermal conductance of the separating interfaces is well understood. Although the thermal conductivity of SnCl₂ is not available in the literature, we expect the value to be around 0.2-0.4 W/m K, as the thermal conductivity of the similar crystalline solids ZnCl₂ and TICI are both below 0.5 W m⁻¹ K⁻¹. Considering that the microstructure is relatively large, on the order of a few microns, the contribution of the interface conductance will be negligible in these composites. With the sample of 20% and 80% SnCl₂/PyDI measured, we can conclude that the thermal conductivities of these composites are around 0.15-0.25 W/m K. Thus, estimating PF of 80 μW/mK², T of 300 K, and K of 0.25 W/mK, we conservatively project ZT of 0.1.

### Example 2: ZnO in P1 and P2

Samples were also prepared with a more conventional n-type inorganic additive, zinc oxide (ZnO). A low-temperature water-based zinc precursor, zinc nitrate hexahydrate, was mixed at concentrations of 20 wt % and 40 wt %, based on the total weight of the composition, in separate samples of P1 and P2. The water-based zinc precursor formed ZnO within the P1 and P2 polymer matrices. Annealing at 200° C. was required to obtain ZnO by combustion reaction, achieved within the polymer matrix. The ZnO did not form secondary domains as large as SnCl₂, when obtained by drop-casting or spin-coating, but instead small discrete particles with fairly homogenous dispersion were observed.

There was difficulty blending the water-based zinc solution (zinc nitrate hexahydrate, and acetylacetonate, 0.3M) with polymers above a certain concentration of initial zinc precursor. The film-forming ability of the composite decreased sharply above 45 wt % zinc precursor due to the different solvents used for the inorganic (ammonia, 0.3M diluted with water 4:1 becomes 0.6 M) and the polymer (toluene). Still, 44 wt % samples of ZnO in P1 showed doubled S and a compared to the analogous P2 sample, leading to a PF around 20 μW/mK² for the P1-ZnO composite, an order of magnitude higher than that for P2. Advantageously, the P1 host matrix allowed for an enhanced PF compared to pure ZnO films (from about 6 to 20 μW/mK²). Significantly, the 40 wt % ZnO hybrids were slightly more conductive and had greater S values than the SnCl₂ hybrid of the same concentration. However, due to the growth of large domains and greater achievable concentrations, the SnCl₂ hybrid polymers ultimately provided the highest PF.

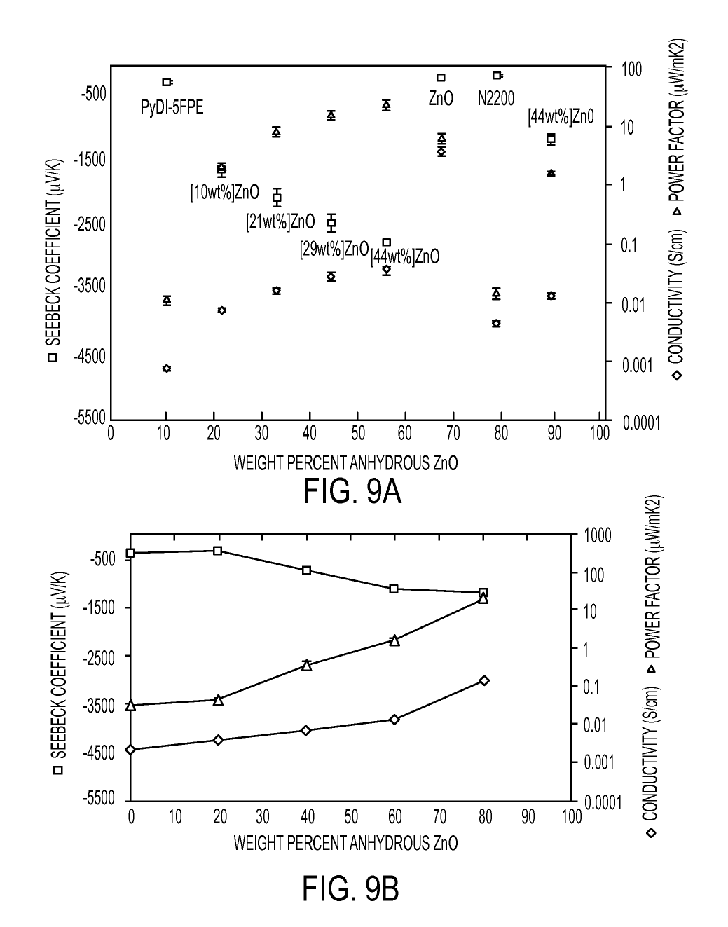

Another example composite was also made in which anhydrous ZnO powder (SigmaAldrich) was blended directly with the P1 polymer following the same procedure as for SnCl₂ (i.e. physical solution blending only, no combustion reaction necessary to obtain ZnO). The results of S, σ, and PF plotted for P1 blended with anhydrous ZnO are shown in FIG. 9B. The results of S, σ, and PF plotted for P1 and P2 compositions blended with ZnO from combustion of aqueous solution, are shown in FIG. 9A. The S and σ for anhydrous ZnO samples do not immediately increase as they do for aqueous-based ZnO samples, but rather rise steadily with increasing dopant concentration, and only reach similar values as 44 wt % aqueous-based samples at around 80 wt % anhydrous ZnO concentrations. This supports in-situ growth of inorganic additives as a beneficial way to improve composite properties, rather than just physical mixing.

### Example 3: Co(acac)₃ doped P3 and P4

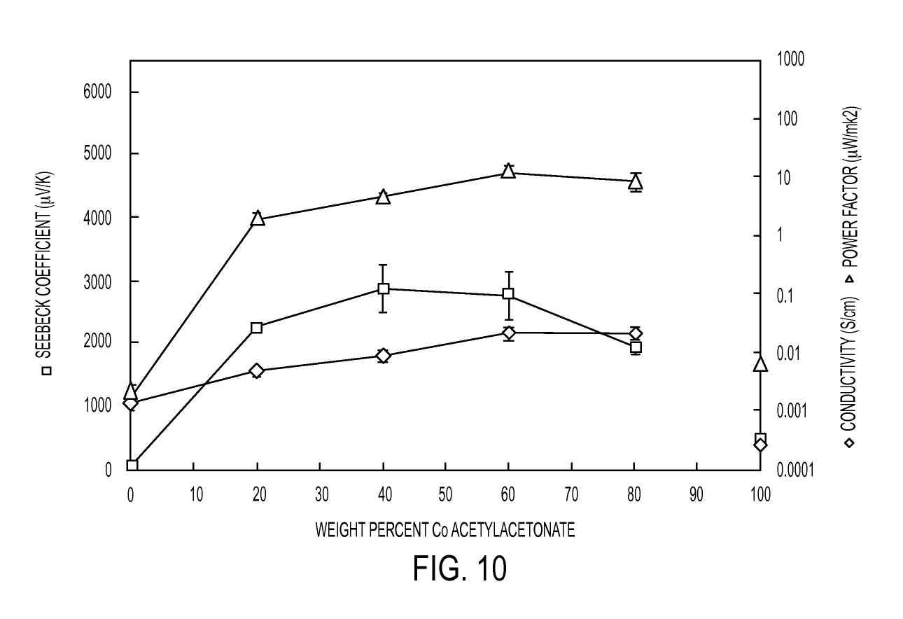

P-type polymers with inorganic additives were made using hole-carrying polymers PQT12 (P3) and PBTTT-C14 (P4). The same procedure used for P1 and P2 was used to make composites of P3 and P4, except that a different organic solvent, chlorobenezene, was used instead of toluene. The weak dopant Co(acac)₃ grew large crystals readily in p-type polymers such as P3 and P4. S>2000 μV/K and power factors of 10 μW/mK² were obtained, with slight increase in hole conductivity (from 0.0013 to 0.021 S/cm). Different morphologies, including elongated uniaxial microcrystals, were demonstrated using 20, 40, and 60 wt % Co(acac)₃ additive within P3 polymer matrix, based on the total weight of the composition, as seen in FIG. 4, where the 20 wt % compositions are shown in the left most set of microscope images, the 40 wt % are the center microscope images and the 60 wt % are the left most images. The bottom images are at a higher magnification than the top images. Similar images (not shown) were obtained for 20 wt %, 60 wt % and 80 wt % Co((acac)₃) blended with P4 (based on the total weight of the compositions). The results of S, σ, and PF plotted for P3 blended with Co((acac)₃) as a function of dopant concentration, where the compositions were obtained using drop casting, are shown in FIG. 10. Considerably higher power factors are anticipated as doping capacity of the inorganic phase is increased, by either using stronger dopants or obtaining more homogeneous dispersion by arresting particle growth at nanoscale dimensions.

S and a can increase simultaneously in the above example composites: the tin compound potentially introduces some new filled states to the polymer where electrons can also thermally access the empty excited states of the polymer. Another mechanism is that the tin compound has some conductivity itself, and a contribution to S can result from the difference in energies of states near the polymer interfaces and states in the interior of the tin chloride structures. Also, the fact that two different polymers give different values of S and a indicates a synergy between the polymer and inorganic phases.

Simple additions of n-doping elements such as S and Al to SnCl₂ and ZnO in the above examples should increase σ. This should not result in accompanying increase in κ because we would remain in the phonon thermal conductivity-dominated regime. Growth of more controlled nanostructures will also increase S and a while decreasing κ further because of additional interface scattering of phonons.

Our use of a novel unipolar n-type polymer and inorganic additives has led to the first demonstration of ZT>0.1 in electron-carrying polymer composites that contain neither highly toxic nor rare elements. Leveraging further recent advances in n-polymer doping, we anticipate equivalent power factors from both composite polarities to be achievable in the near future, and practical efficiencies greater than inorganic materials alone, and thus application of flexible thermoelectric generators for light-power applications utilizing relatively low temperature gradients.

### Example 4

Composites were made utilizing 10 wt % F4TCNQ (a strong p-dopant for the polymer) and 50 wt % Co(acac)3 (weakly doping solid) in the thiophene polymer PQT12. The combination of the strong and weak dopants provided improved results over using just the weak dopant alone. When PQT12 was utilized as the only polymer, factors of about 100 uW/mK2 were acheived.

Polymer blends of PQT12 and PQT12S (same as PQT12 except for sulfur atoms are inserted between the thiophene rings and the dodecyl side chains, making them dodecylthio groups, which results in lower carrier energy level and easier hole-doping) with both the Co(acac)3 and the F4TCNQ additives resulted in increased power factors closer to 200 uW/mK2.

Composites made utilizing using PQT12S alone and both the Co(acac)3 and the F4TCNQ additives resulted in tens of uW/mK2.

### Example 5

A PQT12 polymer was combined with Co(acac)3 dopant alone (no F4TCNQ was added) to form a composite. The crystals in the composite had a high aspect ratio of greater than 5:1, such as 10:1 or more. When the crystals are all oriented so that the length dimension is perpendicular to the electrodes (parallel to the electric fields) then power factors near 90 uW/mK2 were achieved. This compared to 60 uW/mK2 for randomly oriented crystallite samples and 20 uW/mK2 for crystals oriented parallel to the device electrodes (perpendicular to the electric fields).

Thus, when the solid dopant particles had high aspect ratios, which is frequently the case, there were differences in the power factor achieved depending on whether the particles were aligned in a particular direction (e.g., if measurements were made parallel or perpendicular to the alignment). The greatest power factors were achieved when the crystals are all oriented so that the length dimension is perpendicular to the electrodes.

Based on the above results, it appears that the composites having a) strong molecular/soluble dopants in addition to the weakly doping solids, b) polymer blends using two polymers of different carrier energy levels and/or c) aligned crystal inclusions that are all oriented or substantially all oriented so that the length dimension is perpendicular to the electrodes were advantageous in providing increased power factors.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein.

While the present teachings have been illustrated with respect to one or more implementations, alterations and/or modifications can be made to the illustrated examples without departing from the spirit and scope of the appended claims. In addition, while a particular feature of the present teachings may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” Further, in the discussion and claims herein, the term “about” indicates that the value listed may be somewhat altered, as long as the alteration does not result in nonconformance of the process or structure to the illustrated embodiment. Finally, “exemplary” indicates the description is used as an example, rather than implying that it is an ideal.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompasses by the following claims.

1. A thermoelectric polymer composite, comprising:
at least one polymer selected from semiconducting polymers and conducting polymers; and
at least one particle inclusion having one or more dimensions of 1 millimeter or less and at least one dimension of 10 nanometer or more, a sufficient amount of the particle inclusion distributed within the polymer so that the power factor of the composite is greater that the power factor of either the polymer or the particle inclusion separately.

2. The composite of claim 1, wherein the particle inclusion provides a particle inclusion electron donation to the polymer in the case of an n-type polymer, or acquisition of electrons from the polymer in the case of a p-type polymer, that is less than 50% complete as judged by the proportion of formula units in the particle inclusion material being ionized at room temperature.

3. The composite of claim 2, further comprising one or more strongly doping inclusions.

4. The composite of claim 1, wherein the polymer is an n-type polymer.

5. The composite of claim 1, wherein the n-type polymer comprises at least one polymer unit chosen from pyromellitic diimide units, napthalenetetracarboxylic diimide units, perylenetetracarboxylic diimide units, heterocyclic tetracarboxylic diimide units, cyano-substituted vinyl groups, cyanomethylidene-substituted unsaturated rings, fullerene units, pyrazinophthalimide units and triazoledipyridyl units.

6. The composite of claim 5, wherein the n-type polymer further comprises one or more additional conjugating subunits.

7. The composite of claim 1, wherein the n-type polymer is a pyromellitic diimide.

8. The composite of claim 7, wherein the composite exhibits at least one property of the power factor being greater than 1 μW/mK² or the Seebeck coefficient being greater than 50 microvolts/degree K.

9. (canceled)

10. The composite of claim 7, wherein the particle inclusion comprises an inorganic metal compound of two or more elements selected from Sn, Zn, Al, Cl, O and S, wherein the compound includes at least one of Sn, Zn and Al and at least one of Cl, O and S.

11. (canceled)

12. The composite of claim 1, wherein the polymer is a p-type polymer.

13. The composite of claim 12, wherein the p-type polymer comprises at least one polymer unit chosen from thiophene units, 3-alkylthiophene units, thienothiophene units, pyrrole units, furan units, carbazole units, aniline units, ethylenedioxythiophene units, ethylenedithiolate units, methoxyphenylenvinylene units or dialkoxyphenylenevinylene units.

14. The composite of claim 13, wherein the p-type polymer further comprises one or more additional conjugating subunits.

15. The composite of claim 12, wherein the particle inclusion comprises at least one compound chosen from molybdenum trioxide, Cobalt (III) acetylacetonate, Cobalt(III) trifluoroacetylacetonate, Iron (III) trifluoroacetylacetonate, Iron (III) hexafluoroacetylacetonate, manganese (III) acetylacetonate, manganese (III) trifluoroacetylacetonate and manganese dioxide.

16. The composite of claim 12, wherein the particle inclusion comprises at least one oxidizing metal chosen from vanadium (IV), chromium (III), manganese (III), manganese IV, iron(III), cobalt(III), nickel(II), and molybdenum (VI).

17. The composition of claim 12, wherein the composite exhibits at least one property of the power factor being greater than 1 μW/mK² or the Seebeck coefficient being greater than 50 microvolts/degree K.

18. (canceled)

19. The composite of claim 1, wherein the power factor of the composite is greater that the sum of the power factor of the polymer and the power factor of the particle inclusion.

20. The composite of claim 1, wherein the at least one polymer is has a first carrier energy level, the composite including a second polymer that has a second carrier energy level that is lower than the first carrier energy level.

21. A thermoelectric device comprising:
a first electrode and a second electrode;
a thermoelectric composite positioned between the first electrode and the second electrode so that when a temperature differential is applied across the thermoelectric composite, the thermoelectric composite is capable of generating a voltage between the first electrode and the second electrode, the thermoelectric composite comprising:
at least one polymer selected from semiconducting polymers and conducting polymers; and
at least one particle inclusion having one or more dimensions of 1 millimeter or less and at least one dimension of 10 nanometer or more, a sufficient amount of the particle inclusion distributed within the polymer so that the power factor of the composite is greater that the power factor of either the polymer or the particle inclusion separately.

22. The thermoelectric device of claim 21, wherein the particle inclusion provides a particle inclusion electron donation to the polymer in the case of an n-type polymer, or acquisition of electrons from the polymer in the case of a p-type polymer, that is less than 50% complete as judged by the proportion of formula units in the particle inclusion material being ionized at room temperature.

23. The thermoelectric device of claim 21, wherein the composite includes a plurality of the at least one particle inclusions, and wherein a majority of the particle inclusions are oriented so that the length dimension is perpendicular to the electrodes.
